(19) United States
(12) Patent Application Publication
(10) Pub. No.: US 2016/0104699 A1
(43) Pub. Date: Apr. 14, 2016

(54) SEMICONDUCTOR APPARATUS

(71) Applicant: TOYOTA JIDOSHA KABUSHIKI KAISHA, Toyota-shi (JP)

(72) Inventor: Kazunari YAMAMOTO, Miyoshi-shi (JP)

(21) Appl. No.: 14/831,386

(22) Filed: Aug. 20, 2015

(30) Foreign Application Priority Data
Oct. 14, 2014 (JP) 2014-210234

(51) Int. Cl. H01L 27/02; H01L 27/088

(52) U.S. Cl. CPC H01L 27/0248; H01L 27/088

(57) ABSTRACT

There is provided a semiconductor apparatus comprising: a first switching element formed of a wide band gap semiconductor; and a second switching element formed of another wide band gap semiconductor and connected in parallel with the first switching element; wherein the first switching element and the second switching element respectively include a control electrode, a first main electrode and a second main electrode, and respectively have an output capacitance characteristic in which an output capacitance decreases as a voltage between the first main electrode and the second main electrode increases, and the output capacitance characteristics of the first switching element and the second switching element or threshold voltages for respectively turning on/off the first switching element and the second switching element are different from each other.

### BACKGROUND OF THE INVENTION

1. Field of the Invention

The present disclosure is related to a semiconductor apparatus including a switching element.

2. Description of the Related Art

A technology is known, in which a plurality of switching elements formed of silicon carbide are connected in parallel whereas signal transmissions to respective control nodes of the switching elements are shifted by wires connected with the respective control nodes, thereby reducing a surge voltage (for example, see Patent Document 1).

In order to reduce the surge voltage with the aforementioned conventional technology, inductances of the respective wires are required to be set appropriately so as to shift timings of the signal transmissions to the respective control nodes. Therefore, the surge voltage cannot be reduced easily when characteristics of the switching elements are not integrated. However, integration of the characteristics of the switching elements is hardly achieved since the characteristics of the switching elements formed of wide band gap semiconductor such as silicon carbide are likely to vary one by one.

### RELATED ART DOCUMENT

### Patent Document

[Patent Document 1] Japanese Laid-open Patent Publication No. 2009-21395

### SUMMARY OF THE INVENTION

An object of the present disclosure is to provide a semiconductor apparatus capable of reducing the surge voltage without integrating the characteristics of the switching elements.

The following configuration is adopted to achieve the aforementioned object.

In one aspect of the embodiment, there is provided a semiconductor apparatus comprising:

a first switching element formed of a wide band gap semiconductor; and a second switching element formed of another wide band gap semiconductor and connected in parallel with the first switching element; wherein the first switching element and the second switching element respectively include a control electrode, a first main electrode and a second main electrode, and respectively have an output capacitance characteristic in which an output capacitance decreases as a voltage between the first main electrode and the second main electrode increases, and the output capacitance characteristics of the first switching element and the second switching element or threshold voltages for respectively turning on/off the first switching element and the second switching element are different from each other.

Other objects, features and advantages of the present invention will become more apparent from the following detailed description when read in conjunction with the accompanying drawings.

### BRIEF DESCRIPTION OF THE DRAWINGS

FIG. 1 is a diagram for illustrating an example configuration of a semiconductor apparatus.

FIG. 2 is a timing diagram for illustrating example wave forms of operational signals of the semiconductor apparatus.

FIG. 3 is a diagram for showing an example output capacitance characteristic.

FIG. 4 is a diagram for showing another example output capacitance characteristic.

FIG. 5 is an example circuit diagram in which the switching elements are connected in parallel.

FIG. 6 is a diagram for showing an example relationship between gate charge amount and the gate voltage.

FIG. 7 is a diagram for showing a temporal variance in a transition state shown in FIG. 6.

### DETAILED DESCRIPTION OF THE PREFERRED EMBODIMENTS

In the following, embodiments are described in detail with reference to appended drawings.

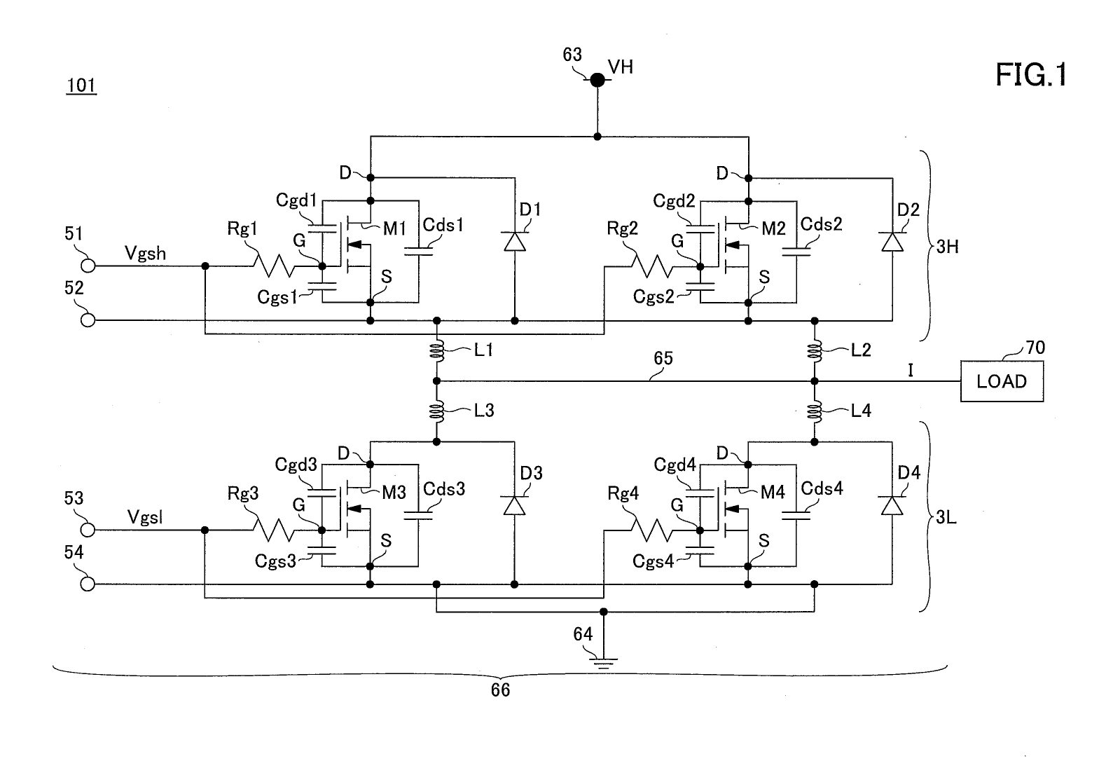

FIG. 1 is a diagram for illustrating an example configuration of a semiconductor apparatus of the present embodiment. The semiconductor apparatus of the present embodiment is an example of a semiconductor circuit including a driving unit for driving an inductive load 70 (such as an inductor or a motor) by turning on and off the switching elements.

A power conversion apparatus for converting input electric power into output electric power by switching on/off the switching elements is exemplified as an apparatus in which one or more of the semiconductor apparatuses are included. A converter for stepping-up or stepping-down DC voltage, an inverter for converting electric powers of DC power and AC power, etc., are exemplified as the power conversion apparatus.

In FIG. 1, an example of a power conversion apparatus 101 in which the semiconductor apparatuses are disposed at high side and low side is shown. The power conversion apparatus 101 includes an arm circuit 66 in which the semiconductor apparatus 3H disposed at high side with respect to a center node 65 and the semiconductor apparatus 3L disposed at the low side with respect to the center node 65 are connected in series. For example, when the power conversion apparatus 101 is used as an inverter for driving a three-phase motor, three of the arm circuits 66 are included, the same as number of phases in the motor. The load 70 is connected with the center node 65.

The semiconductor apparatus 3H includes switching elements M1 and M2 connected between the center node 65 and a power source node 63, and the semiconductor apparatus 3L includes switching elements M3 and M4 connected between the center node 65 and ground node 64. For example, a positive electrode of a DC power source such as a secondary battery is connected with the power source node 63 while a negative electrode of the DC power source is connected with the ground node 64.

The switching element M1 is an example of a first switching element formed of a wide band gap semiconductor, and the switching element M2 is an example of a second switching element formed of a wide band gap semiconductor. Similarly, the switching element M3 is an example of a first switching element formed of a wide band gap semiconductor, and the switching element M4 is an example of a second switching element formed of a wide band gap semiconductor.

The wide band gap semiconductor has a band gap greater than that of silicon (Si). Silicon carbide (SiC), gallium nitride (GaN), gallium oxide (Ga₂O₃), etc., are exemplified as the wide band gap semiconductor.

For example, the switching elements M1, M2, M3 and M4 are unipolar semiconductor switches including a control electrode, a first main electrode and a second main electrode. For example, the unipolar semiconductor switch is a unipolar transistor including a gate electrode G that is an example of the control electrode, a drain electrode D that is an example of the first main electrode and a source electrode S that is an example of the second main electrode. A MOSFET (Metal Oxide Semiconductor Field Effect Transistor) including the gate electrode G, the drain electrode D and the source electrode S is a specific example of the unipolar transistor. For example, the switching elements M1, M2, M3 and M4 are N channel MOSFETs (NMOS transistors).

The switching elements M1 and M2 are connected in parallel. That is, the drain electrode D of the switching element M1 is connected with the drain electrode D of the switching element M2, while the source electrode S of the switching element M1 is connected with the source electrode S of the switching element M2. Similarly, the switching elements M3 and M4 are connected in parallel.

The respective drain electrodes D of the switching elements M1 and M2 are commonly connected with the power source node 63, while the respective source electrodes S of the switching elements M1 and M2 are commonly connected with the center node 65. The respective drain electrodes D of the switching elements M3 and M4 are commonly connected with the center node 65, while the respective source electrodes S of the switching elements M3 and M4 are commonly connected with the ground node 64.

A diode D1 is connected between the source electrode S and the drain electrode D of the switching element M1. The anode of the diode D1 is connected with the source electrode S while the cathode of the diode D1 is connected with the drain electrode D. Similarly, diodes D2, D3 and D4 are respectively connected with the switching elements M2, M3 and M4.

The semiconductor apparatus 3H includes a gate driving terminal 51 to which the respective gate electrodes G of the switching elements M1 and M2 disposed at high side with respect to the center node 65 are commonly connected. The gate driving terminal 51 is an example of a control terminal to which a gate driving signal “Vgsh” for turning on/off the switching elements M1 and M2 is provided. The gate driving signal “Vgsh” is a voltage signal whose reference voltage is set to be a potential of the gate driving reference terminal 52. The gate driving reference terminal 52 is a node connected with the center node 65 and the source electrodes S of the switching elements M1 and M2.

A number of the gate driving terminals, to which the gate driving signal “Vgsh” is input, can be reduced by commonly connecting the gate electrodes G of the switching elements M1 and M2 to the gate driving terminal 51. Also, as for the voltage “Vgs” applied between the gate electrode G and the source electrode S in the respective switching elements M1 and M2, a shift of the voltage “Vgs” between the switching elements M1 and M2 can be prevented by commonly connecting the gate electrodes G of the switching elements M1 and M2 to the gate driving terminal 51.

The semiconductor apparatus 3L includes a gate driving terminal 53 commonly connected to the gate electrodes G of the respective switching elements M3 and M4 which are disposed at the low side with respect to the center node 65. The gate driving terminal 53 is an example of the control terminal to which a gate driving signal “Vgs1” for turning on/off the switching elements M3 and M4 is provided. The gate driving signal “Vgs1” is a voltage signal whose reference voltage is set to be a potential of the gate driving reference terminal 54. The gate driving reference terminal 54 is a node connected with the ground node 64 and the source electrodes S of the respective switching elements M3 and M4.

A number of the gate driving terminals, to which the gate driving signal “Vgs1” is input, can be reduced by commonly connecting the gate electrodes G of the switching elements M3 and M4 to the gate driving terminal 53. Also, as for the voltage “Vgs” applied between the gate electrode G and the source electrode S in the respective switching elements M3 and M4, a shift of the voltage “Vgs” between the switching elements M3 and M4 can be prevented by commonly connecting the gate electrodes G of the switching elements M3 and M4 to the gate driving terminal 53.

In FIG. 1, a gate resistor Rg1 is connected in series between the gate driving terminal 51 and the gate electrode G of the switching element M1, and a gate resistor Rg2 is connected in series between the gate driving terminal 51 and the gate electrode G of the switching element M2. The resistance of the gate resistor Rg1 is equal to the resistance of the gate resistor Rg2. Similarly, in FIG. 1, a gate resistor Rg3 is connected in series between the gate driving terminal 53 and the gate electrode G of the switching element M3, and a gate resistor Rg4 is connected in series between the gate driving terminal 53 and the gate electrode G of the switching element M4. The gate resistance of the resistor Rg3 is equal to the resistance of the gate resistor Rg4.

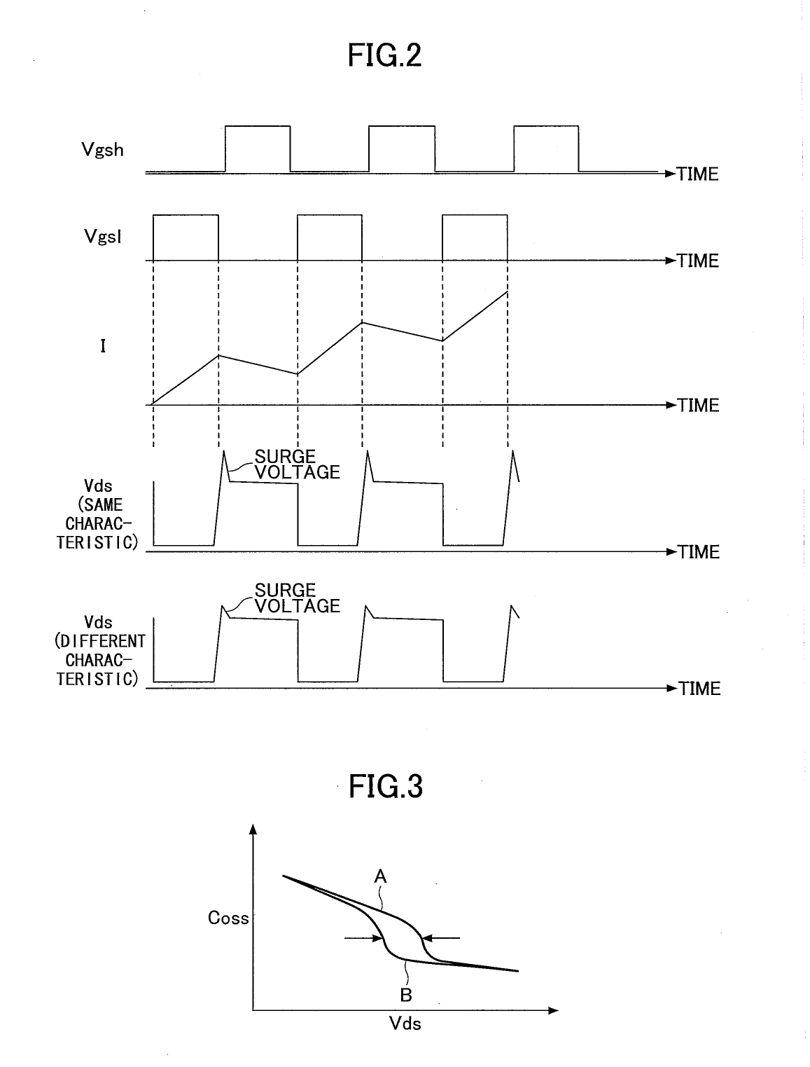

FIG. 2 is a timing diagram for illustrating example wave forms of operational signals of the semiconductor apparatus. The switching elements M3 and M4 are switched on (being conductive) when the gate driving signal “Vgs1” is at high level. Since the gate driving signal “Vgsh” is a reverse phase signal of the gate driving signal “Vgs1”, the switching elements M1 and M2 are switched off when the switching elements M3 and M4 are switched on, while they are switched on when the switching elements M3 and M4 are switched off.

Upon the gate driving signal “Vgs1” turning from low level to high level, the voltage VH is applied to the load 70, which causes load current I flowing through the load 70 to start to increase with an inclination VH/L. The VH is a voltage between the power source node 63 and the ground node 64, and the L is an inductance of the load 70. Upon the gate driving signal “Vgs1” turning from high level to low level, the forward voltage VF across the diode D1 or the diode D2 is applied to the load 70, which causes the load current I to start to decrease with inclination −VF/L. Thus, a state of the load current I varies upon the gate driving signal “Vgs1” turning from high level to low level thereby turning the switching elements M3 and M4 from on to off. Therefore, a surge voltage (see FIG. 2) according to a product of parasitic inductances L3 and L4 by a variance rate of the load current I is generated when the switching elements M3 and M4 are turning from on to off while the load current I is flowing from the load 70 to the switching element M3 and M4. The parasitic inductance L3 is an inductance caused by a line connecting the drain electrode D of the switching element M3 with the center node 65, and the parasitic inductance L4 is an inductance caused by a line connecting the drain electrode D of the switching element M4 with the center node 65.

Output capacitance characteristics of the switching elements M3 and M4 are different from each other. The output capacitance characteristic means a characteristic of an output capacitance with respect to the voltage between the first main electrode and the second main electrode. For example, in a case where the switching element is a unipolar semiconductor switch, the voltage between the first main electrode and the second main electrode corresponds to the voltage “Vds” generated between the drain electrode D and the source electrode S of the switching element. Also, the output capacitance is a sum of a parasitic capacitance between the first main electrode and the second main electrode of the switching element and a parasitic capacitance between the control electrode and the first main electrode of the switching element. For example, in a case where the switching element is a unipolar semiconductor switch, the output capacitance “Coss” of the switching element is the sum of parasitic inductance “Cds” between the drain electrode D and the source electrode S and a parasitic capacitance “Cgd” between the gate electrode G and the drain electrode D (Coss=Cds+Cgd). The output capacitance of the switching element has a characteristic where the output capacitance is decreased as the voltage between the first main electrode and the second main electrode is increased.

Additionally, in FIG. 1, “Cds1”, “Cds2”, “Cds3” and “Cds4” respectively express the parasitic capacitances “Cds” of the switching elements M1, M2, M3 and M4. “Cgd1”, “Cgd2”, “Cgd3” and “Cgd4” respectively express the parasitic capacitances “Cgd” of the switching elements M1, M2, M3 and M4. “Cgs1”, “Cgs2”, “Cgs3” and “Cgs4” respectively express the parasitic capacitances “Cgs” between the gate electrode and the source electrode in the switching elements M1, M2, M3 and M4.

By connecting the switching elements M3 and M4 in parallel, whose output capacitance characteristics are different from each other, one of the output capacitances of the switching elements M3 and M4 can be used for reducing the surge voltage.

For example, when the switching elements M3 and M4 are turned off, current generated by energy accumulated in the lines having parasitic inductances L3 and L4 flows through the switching elements M3 and M4 that have the output capacitances “Coss”. Since the output capacitances “Coss” of the switching elements M3 and M4 serve as capacitances of external capacitors respectively attached to the switching elements M3 and M4, the voltages “Vds” of the switching elements M3 and M4 increase due to the current flowing through the switching elements M3 and M4 that have the output capacitances “Coss”.

The output capacitances “Coss” of the switching elements M3 and M4 at the same voltage “Vds” are different from each other since the output capacitance characteristics of the switching elements M3 and M4 are different from each other. Therefore, one of the output capacitances “Coss” of the switching elements M3 and M4 becomes smaller prior to the other in increasing the voltages “Vds” of the switching elements M3 and M4.

For example, as shown in FIG. 3, in a case where the output capacitance characteristics of the switching elements A and B are different from each other, the output capacitance “Coss” of the switching element B becomes smaller prior to that of the switching element A in increasing the voltages “Vds”. FIG. 3 is a diagram for showing an example output capacitance characteristic, where inflection points in respective curved lines for expressing the output capacitance characteristics of the switching elements A and B are different from each other.

According to a capacitor principle, an increasing rate of the voltage “Vds” becomes greater as the output capacitance “Coss” becomes smaller. In FIG. 3, especially, when the output capacitance “Coss” comes around the inflection point due to the increase of the voltage “Vds”, the output capacitance “Coss” rapidly decreases to accelerate the increasing rate of voltage “Vds”. Therefore, the increasing rate of the voltage “Vds” in the switching element B rapidly increases prior to that in the switching element A since the output capacitance “Coss” of the switching element B becomes smaller prior to that of the switching element A. Thus, there is a timing at which the voltage “Vds” of the switching element A is less than the voltage “Vds” of the switching element B.

At the timing when the voltage “Vds” of the switching element A is less than the voltage “Vds” of the switching element B, the switching element A is in a state as if an external capacitor were attached to the switching element A in comparison to the switching element B. In accordance with circuit theory, it is obvious that the surge voltage where the external capacitor is provided is less than that where the external capacitor is not provided. Therefore, the surge voltage generated at turning off the switching elements A and B can be reduced by using the output capacitance “Coss” of the switching element A.

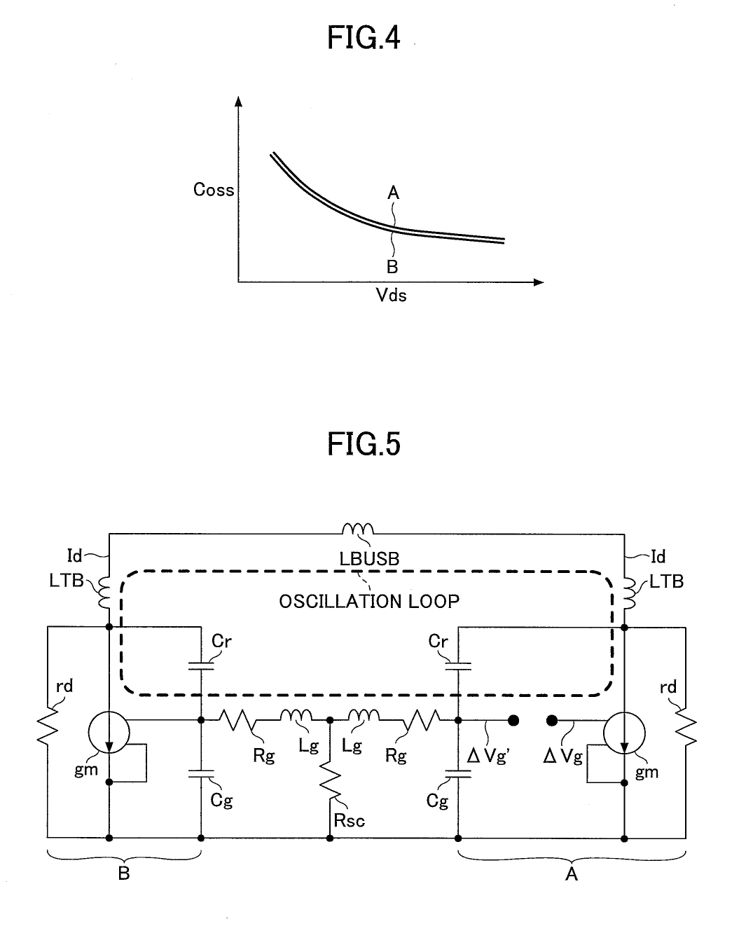

Additionally, in order to reduce the surge voltage, the output capacitance characteristics of the switching elements A and B may be only different from each other, whereas the curved lines expressing the output capacitance characteristics of the respective switching elements A and B may not include the inflection points as shown in FIG. 3. For example, the curved lines for expressing the output capacitance characteristics of the respective switching elements A and B may be those shown in FIG. 4, where the output capacitance “Coss” of the switching element A is defined to be greater than that of the switching element B at the same voltage “Vds”.

Thus, the surge voltage at turning off the switching elements connected in parallel can be reduced by using the output capacitance of the switching element whose output capacitance decreases delayed compared to the other. For example, if the output capacitance characteristics of the switching elements M3 and M4 are different from each other, the surge voltage generated at turning off the switching elements M3 and M4 can be reduced. Similarly, if the output capacitance characteristics of the switching elements M1 and M2 are different from each other, the surge voltage generated at turning off the switching elements M1 and M2 can be reduced.

By the way, in a case where the resistance value of the gate resistor Rg is inappropriate, an oscillation phenomenon may occur, where drain current Id increases and decreases upon the voltage “Vds” or the voltage “Vgs” variing in one of the switching elements A and B. The oscillation phenomenon will be described with reference to FIG. 5.

FIG. 5 is an example circuit diagram in which the switching elements A and B are connected in parallel. Four elements of “rd”, “gm”, “Cr” and “Cg” show an equivalent circuit of a chip of the switching element. The “rd” shows a drain resistance, the “gm” shows a mutual conductance, the “Cr” shows a feedback capacitance, and the “Cg” shows a gate capacitance. The “Rg” shows a gate resistance, the Lg shows a parasitic inductance of a gate resistor wiring, the “LTB” shows a parasitic inductance of drain wiring, and the “LBUSB” shows a parasitic inductance of wiring for connection in parallel.

When the voltage “Vds” or the gate voltage “Vg” in the switching element A of the two switching elements varies, the drain current Id flowing through the switching element A varies. When the drain current Id varies to increase, drain current Id flowing through the other switching element B varies to decrease. The reason is that a sum of the values of the drain currents Id flowing through the switching element A and B are constant values since the load current flowing through the load 70 is divided into the current flowing through the switching element A and current flowing through the switching element B.

The voltage “Vds” in the switching element B decreases in accordance with the decrease of the drain current Id flowing through the switching element B. When the voltage “Vds” in the switching element B decreases, the gate voltage “Vg” in the switching element B also decreases due to the feedback capacitance Cr of the switching element B. After a delay time passes, due to existence of the parasitic inductance Lg and the gate capacitance, the gate voltage “Vg” decreases in the switching element A whose drain current Id first increases, thereby decreasing the drain current Id flowing through the switching element A.

Thus, the oscillation phenomenon occurs, where drain current Id increases and decreases repeatedly in between the two switching elements. The load current flowing through the load 70 varies little since the value of the current is moving between the two switching elements. In order to prevent such an oscillation phenomenon, the resistance value of the gate resistor Rg is set so that a phase margin and a gain margin in a loop gain G (s) of the circuit in which the switching element A and B are connected in parallel become greater than or equal to a certain value. The loop gain G (s) is given by the following formula.

$$G ( s ) ≡ \frac{Δ {V}_{g}^{′}}{Δ {V}_{g}} = - {g}_{m} {r}_{d} \frac{{C}_{r}}{{C}_{g} + {c}_{r}} ( 1 - ( \frac{{R}_{SC}}{{R}_{SC} + ( {R}_{g} + \frac{1}{s ( {C}_{r} + {C}_{g} )} )} + 1 ) \frac{\frac{1}{s ( {C}_{r} + {C}_{g} )}}{{R}_{g} + \frac{{R}_{SC} ( {R}_{g} + \frac{1}{s ( {C}_{r} + {C}_{g} )} )}{{R}_{SC} ( {R}_{g} + \frac{1}{s ( {C}_{r} + {C}_{g} )} )} + \frac{1}{s ( {C}_{r} + {C}_{g} )}} ) \\ {g}_{m} {r}_{d} ≡ \frac{\partial {V}_{ds}}{\partial {V}_{g}} = \frac{\partial {V}_{ds}}{\partial {I}_{d}} \frac{\partial {I}_{d}}{\partial Vg} \qquad [ Math . 1 ]$$

For example, if the resistance value of the gate resistor Rg is infinite, the connection of the respective gate electrodes of the switching elements A and B is equivalent to being separated from each other. Therefore, in actual use, preferably, the resistance value of the gate resistor Rg is set to be equal to or greater than 2Ω and equal to or less than 400Ω.

By the way, when the switching elements A and B whose threshold voltages “Vth” of the control electrodes are different from each other are connected in parallel, turning off only one of the switching elements prior to the other can be prevented since the switching elements A and B affect each other. That is, one of the switching elements can be turned off affected by the other switching element connected in parallel, thereby reducing the surge voltage in comparison to a case where the respective switching elements are turned off separately. Additionally, the resistance value of the gate resistor Rg is set to be small so that the phase margin and the gain margin in a loop gain G (s) of the circuit in which the switching elements A and B are connected in parallel become greater than or equal to a certain value.

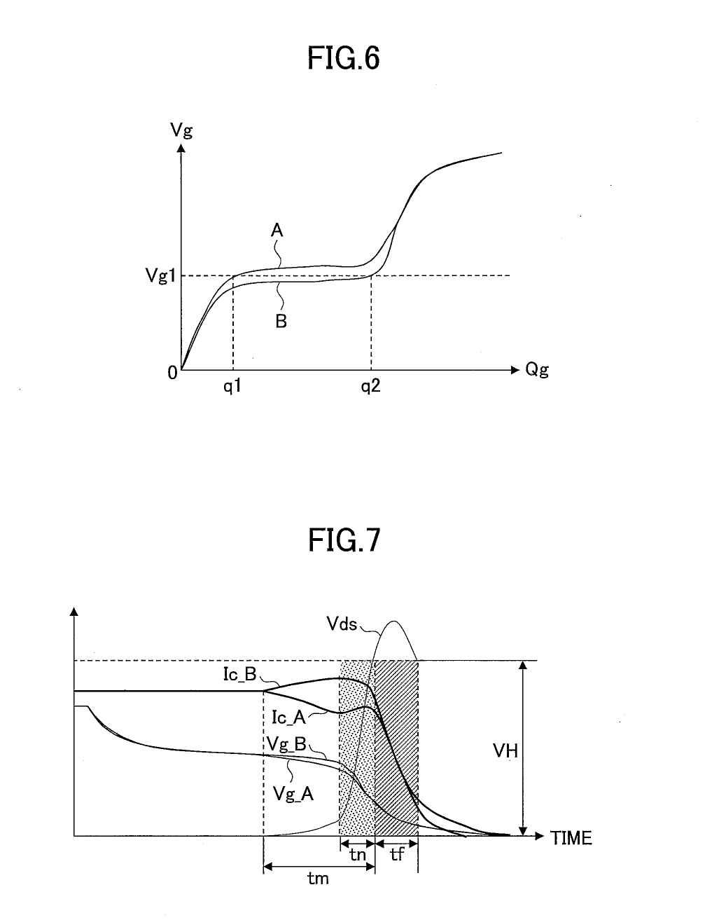

FIG. 6 is a diagram for showing an example relationship between gate charge amount Qg and the gate voltage Vg. The gate charge amount Qg means an electric charge amount in the gate electrode that is an example of the control electrode of the switching element. In FIG. 6, the threshold voltage “Vth” of the gate electrode of the switching element A is greater than the threshold voltage “Vth” of the gate electrode of the switching element B.

The threshold voltage “Vth” is a voltage required to form a channel in the switching element for the drain current to flow. The threshold voltage “Vth” is applied to the gate electrode so as to turn on/off the conductivity of the switching element. When the gate voltage “Vg” is greater than the threshold voltage “Vth”, the switching element is turned on so that the drain current flows through the switching element. When the gate voltage “Vg” is less than the threshold voltage “Vth”, the switching element is turned off to prevent the drain current flowing through the switching element.

Since the gate electrode of the switching element A is connected to the gate electrode of the switching element B through the two gate resistors Rg that have respectively the same resistance value, the gate voltage “Vg” of the switching element A is almost equal to the gate voltage “Vg” of the switching element B. In Vg-Qg curved lines shown in FIG. 6, at an operational point of a certain timing (a timing at which the gate voltage “Vg” decreases to a voltage Vgl), the channel in the switching element A is about to vanish while the channel in the switching element B is being formed. The “q1” shows a gate charge amount just before the channel in the switching element A vanishes, while the “q2” shows the gate charge amount in forming the channel in the switching element B.

After this timing, although the gate voltage “Vg” shown as a horizontal dotted line in FIG. 6 decreases from moment to moment, it takes time to reach a voltage for having the channel in the switching element B vanish. Therefore, the gate voltage “Vg” in the switching element A does not directly decrease to 0 V, thereby having the decreasing rate of the gate voltage “Vg” in the switching element A be suppressed.

FIG. 7 is a diagram for showing a transition state shown in FIG. 6 with a graph for showing temporal variance.

Since the channel in the switching element A vanishes prior to that in the switching element B, the drain current Ic_A starts to decrease prior to the drain current Ic_B. Since the load current IL is forced to flow from the load 70 to the respective switching elements, the drain current Ic_B of the switching element B is temporarily increased during a period (“tm”-tn) so that the sum of the drain currents flowing through the switching element A and switching element B becomes equal to the load current IL.

Additionally, although, in FIG. 6, the gate voltages “Vg” of the switching elements A and B are shown as though they decreased all together, actually, as shown in FIG. 7, the respective gate voltages “Vg” slightly shift in between the switching elements A and B during the decrease. The shift is caused by a difference between the gate charge amount Qg in the switching element A and the gate charge amount Qg in the switching element B.

The gate voltage “Vg” decreases while the feedback capacitance tends to raise it. However, gate voltages “Vg” are not similarly raised in the switching element A and the switching element B since the feedback capacitances in the respective switching elements are uneven. When the commutation occurs in another switching element (opposite arm) connected in series with both of the switching elements A and B to fix the voltages “Vds” between the drain electrode and the source electrode in the respective switching elements A and B at the voltage VH (see FIG. 1), charging the gate electrodes due to the feedback capacitance is stopped, thereby causing the gate voltage Vg_A and the gate voltage Vg_B to conform. The gate voltage Vg_B in the switching element B is greater than the gate voltage Vg_A in the switching element A during the period “tm”. When the gate voltage Vg_A becomes equal to the gate voltage Vg_B, the gate voltage Vg_A and the gate voltage Vg_B start to decrease while having the same voltage value (period “tf”).

As described above, the period “tm” occurs due to the difference of the respective gate charge amounts Qg between the switching element A and the switching element B, while the difference between the drain current Ic_A and the drain current Ic_B is caused due to the difference between the threshold voltages “Vth”.

Therefore, by connecting the switching elements A and B in parallel, whose threshold voltages “Vth” of the respective control electrodes are different from each other, the load current IL is divided to follow through the switching element A and thorough the switching element B in the period “tm”, thereby suppressing values of the drain current Ic_A and the drain current Ic_B. That is, a peak value of the surge voltage generated between the drain electrode and the source electrode during the period “tf” can be reduced since the drain current flows without concentrating into one of the switching elements.

As described above, according to the present embodiment, by connecting in parallel the switching elements, whose output capacitance characteristics or threshold voltages are different from each other, the characteristic of one switching element can be used for reducing the surge voltage. Therefore, the surge voltage can be reduced without integrating the characteristics of the switching elements.

Yields in manufacturing the switching elements are likely to be low in the related art since the characteristic of the switching elements formed of wide band gap semiconductor are likely to vary one by one. However, according to the present embodiment, the yield can be improved since the integration of the characteristics of the switching elements is not required.

Herein above, although the invention has been described with respect to a specific embodiment, the appended claims are not to be thus limited. It should be understood that the various changes, substitutions, and alterations could be made hereto without departing from the spirit and scope of the claims. Further, all or part of the components of the embodiments described above can be combined.

For example, the switching element of the present embodiment may be a bipolar semiconductor switch such as a bipolar transistor. An IGBT (Insulated Gate Bipolar Transistor) is exemplified as the bipolar transistor. The IGBT includes a gate electrode that is an example of the control electrode, a collector electrode that is an example of the first main electrode, and an emitter electrode that is an example of the second main electrode.

Also, since respective parts included in the switching element are usually formed of minute cells, the connection in parallel may mean that the cells are connected in parallel or that the switching elements as unit parts are connected in parallel.

The present application is based on Japanese Priority Application No. 2014-210234, filed on Oct. 14, 2014, the entire contents of which are hereby incorporated by reference.

What is claimed is:

1. A semiconductor apparatus comprising:
a first switching element formed of a wide band gap semiconductor; and
a second switching element formed of another wide band gap semiconductor and connected in parallel with the first switching element; wherein
the first switching element and the second switching element respectively include a control electrode, a first main electrode and a second main electrode, and respectively have an output capacitance characteristic in which an output capacitance decreases as a voltage between the first main electrode and the second main electrode increases, and
the output capacitance characteristics of the first switching element and the second switching element or threshold voltages for respectively turning on/off the first switching element and the second switching element are different from each other.

2. The semiconductor apparatus as claimed in claim 1, wherein inflection points in respective curved lines showing the output capacitance characteristics of the first switching element and the second switching element are different from each other.

3. The semiconductor apparatus as claimed in claim 1, further comprising a gate driving terminal commonly connected to the control electrode of the first switching element and the control electrode of the second switching element.
